(19) United States
(12) Patent Application Publication
(10) Pub. No.: US 2009/0229860 A1
(43) Pub. Date: Sep. 17, 2009

(54) Green sheet for multi-layered electronics parts and manufacturing method for green chip using the same

(75) Inventors: Dong Joo Shin, Seoul (KR); Young Woo Lee, Suwon-si (KR); Jeong Min Cho, Yongin-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/153,014

(22) Filed: May 12, 2008

(30) Foreign Application Priority Data
Mar. 17, 2008 (KR) 10-2008-0024426

(51) Int. Cl. H05K 1/00; H05K 3/00

(52) U.S. Cl. 174/250; 29/842

(57) ABSTRACT

The present invention relates to a green sheet for multi-layered electronics parts and a manufacturing method of a green chip using the same. The present invention provides a green sheet for multi-layered electronics parts including a green sheet; and an internal electrode formed on the green sheet and having a gap formed therein.

Further, the present invention provides the manufacturing method of the green chip using the green sheet for the multi-layered electronics parts.

### CROSS-REFERENCE TO RELATED APPLICATIONS

This application claims the benefit of Korean Patent Application No. 10-2008-0024426 filed with the Korea Intellectual Property Office on Mar. 17, 2008, the disclosure of which is incorporated herein by reference.

### BACKGROUND OF THE INVENTION

1. Field of the Invention

The present invention relates to a green sheet for multi-layered electronic parts and a manufacturing method for a green chip using the same; and more particularly, to a green sheet for multi-layered electronics parts and a manufacturing method for a green chip using the same to form the green chip by forming a gap in an internal electrode of the green sheet and by cutting the gap.

2. Description of the Related Art

Generally, an MLCC (Multi-Layered Ceramic Capacity) is a chip-type condenser which is mounted on a printed circuit board of various electronics parts including a mobile communication terminal, a notebook, a computer, a personal digital assistance (PDA) and plays an important role to charge or discharge electricity. The MLCC has various sizes and stacking patterns according to use and capacity.

Recently, the MLCC has been subjected to miniaturization and ultra-high capacity and the miniaturization and the ultra-high capacity can be realized by thinning the internal electrode, and thinning and stacking a dielectric layer with high density.

A method of manufacturing the MLCC includes a molding process of continuously applying slurry-type ceramic onto a carrier film in a thin thickness of several micrometers to tens micrometers, a printing process of manufacturing a ceramic green sheet by printing a predetermined internal electrode pattern onto a surface of the applied ceramic, a delaminating process of delaminating the ceramic green sheet cut from the carrier film in a predetermined shape, a stacking process of stacking the ceramic green sheet separated from the carrier film in the predetermined number of layers, a compressing process of manufacturing a green bar by compressing the stacked ceramic green sheet at a predetermined pressure, a cutting process of manufacturing green chips by cutting the compressed green bar in a chip size, and a process of plasticizing and sintering the cut green chips after polishing the cut green chips.

Herein, in the process of cutting the compressed green bar to manufacture the green chips, since a cutter cuts the green chips with being in direct contact with the internal electrode printed on the green sheet, a stress and a damage remarkably occur on cut surfaces of the green chips and thus a defect rate of the chip is increased, whereby a yield and reliability of the green chip are reduced.

### SUMMARY OF THE INVENTION

Accordingly, the present invention is made to solve the above-mentioned problems. An advantage of the present invention is that it provides a green sheet for a multi-layered electronics parts and a method of manufacturing a green chip using the same, capable of improving a yield and reliability of the green chip by forming a gap in an internal electrode of the green sheet and cutting the gap in the cutting process for manufacturing the green chip to minimize a cutting stress and a cutting damage, and reducing a failure rate of the chip.

In order to achieve the above-mentioned advantages, a green sheet for multi-layered electronics parts in accordance with an aspect of the present invention may include a green sheet; and an internal electrode formed on the green sheet and being provided with a gap formed therein.

Herein, the gap may be formed in a center portion of the internal electrode.

The internal electrode may be formed by a screen printing method or a vacuum thin-film depositing method.

In order to achieve the above-mentioned advantages, a method of manufacturing a green chip using a green sheet for multi-layered electronics parts in accordance with another aspect of the present invention includes the steps of: (a) providing a green sheet; (b) forming an internal electrode with a gap formed therein on the green sheet; (c) stacking the green sheet in which the internal electrode is formed; and (d) cutting the stacked green sheet along a center of the gap of the internal electrode, which serves as a cutting line.

Herein, the gap may be formed in a center portion of the internal electrode.

The internal electrode may be formed by a screen printing method or a vacuum thin-film depositing method.

In the step (c), the gap is positioned on the cutting line between adjacent internal electrodes at the time of stacking the green sheet.

The method of manufacturing the green chip using the multi-layered electronics parts may further include a polishing step of removing the gap after the step (d).

In the step (d), the green sheet may be cut by using a blade along the cutting line and a width of the gap may be equal to or larger than a width of the blade.

### BRIEF DESCRIPTION OF THE DRAWINGS

These and/or other aspects and advantages of a green sheet for multi-layered electronics parts and a manufacturing method of a green chip using the same in accordance with the present invention will become apparent and more readily appreciated from the following description of the embodiments, taken in conjunction with the accompanying drawings of which:

FIG. 1 is a plan view illustrating a green sheet for multi-layered electronics parts in accordance with an embodiment of the invention;

FIG. 2 is a plan view illustrating a mask for forming an internal electrode of the green sheet for the multi-layered electronics parts in accordance with the embodiment of the invention; and

FIGS. 3 to 7 are process cross-sectional views sequentially illustrated to explain a method of manufacturing a green chip using the green sheet for the multi-layered electronics parts in accordance with the embodiment of the invention.

### DETAILED DESCRIPTION OF THE PREFERRED EMBODIMENTS

### Green Sheet for Multi-Layered Electronics Parts

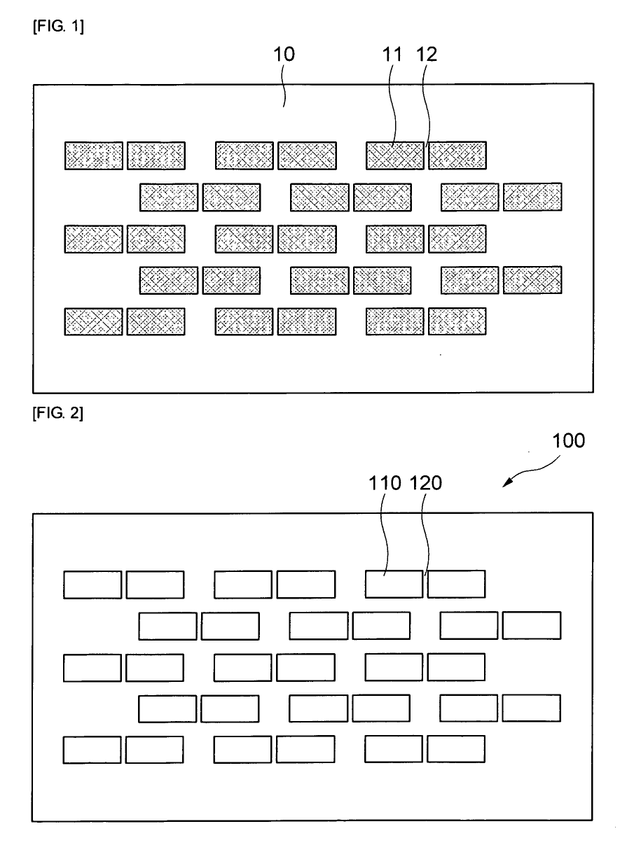

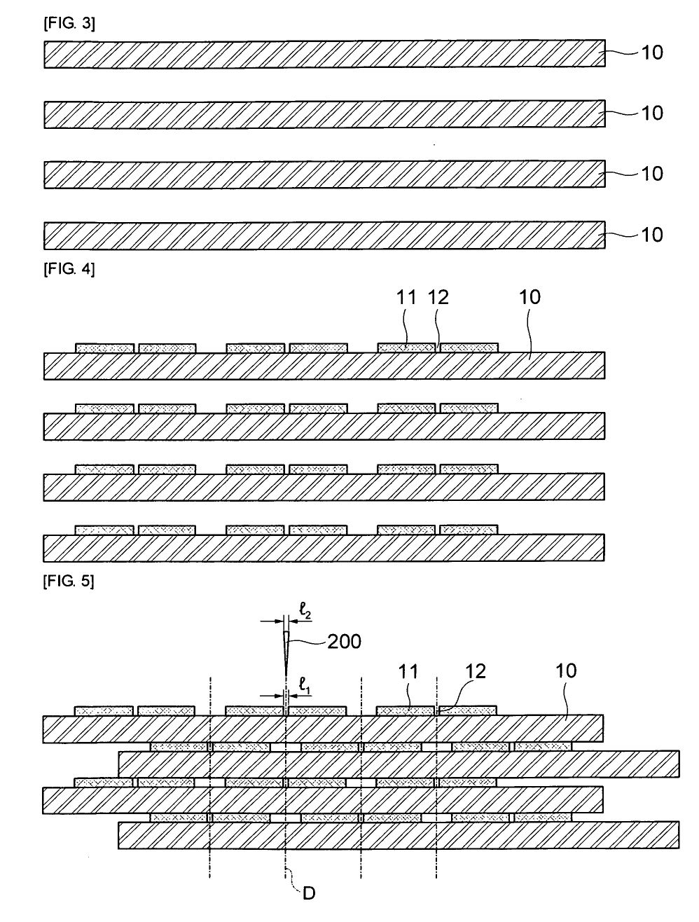

A green sheet for multi-layered electronics parts in accordance with an embodiment of the present invention will be described in detail with reference to FIG. 1 and FIG. 2.

FIG. 1 is a plan view illustrating the green sheet for the multi-layered electronics parts in accordance with the embodiment of the present invention; and FIG. 2 is a plan view illustrating a mask for forming an internal electrode of the green sheet for the multi-layered electronics parts in accordance with the embodiment of the present invention.

First, as shown in FIG. 1, the green sheet for the multi-layered electronics parts in accordance with the embodiment of the present invention includes a green sheet 10 and a plurality of internal electrodes 11 which are formed on the green sheet 10 and have gaps 12 in the inside thereof.

The green sheet 10 may be generally manufactured in a thickness of several micrometers by applying a slurry onto a carrier film and drying the slurry after preparing slurry by mixing BaTiO₃ powder with a ceramic additive, an organic solvent, a plasticizer, a binder, and a dispersant by using a basket mill.

The gaps 12 formed in the internal electrodes 11 are areas cut in a cutting process for manufacturing the green chip fabricating the green chip. The gaps 12 may be formed in center portions of the internal electrodes 11.

Herein, as described above, the green chip is manufactured by cutting a green bar manufactured by stacking and compressing the green sheet in a form of a unit element.

As shown in FIG. 2, the internal electrodes 11 having the gaps 12 formed therein may be formed by using a mask 100 for exposing an internal electrode forming area 110 and covering a gap forming area 120.

The internal electrodes 11 in which the gaps 12 may be formed by a screen printing method or a vacuum thin-film depositing method.

Herein, in case of using the screen printing method, metallic powder for forming the internal electrodes 11 is manufactured by using paste and the internal electrodes 11 can be printed on the green sheet 10 by squeezing the paste by using the mask 100 as a screen.

In case of using the vacuum thin-film depositing method, a material of the internal electrode 11, for example, a material such as Ni can be attached to the green sheet 10 in a form of the electrode by covering the green sheet 10 with the mask 100, positioning the separate green sheet 10 covered with the mask 100, and heating and evaporating the material by irradiating an electronic beam to the material.

As described above, in the green sheet for the multi-layered electronics parts in accordance with the embodiment of the present invention, a cutting stress and a cutting damage can be minimized by forming the gaps 12 in the internal electrodes 11 of the green sheet 10 and cutting not the internal electrodes 11 but the gaps 12 in the cutting process for manufacturing the green chip.

Therefore, the present invention has an advantage in that a yield and reliability can be improved by reducing a defect rate of the green chip.

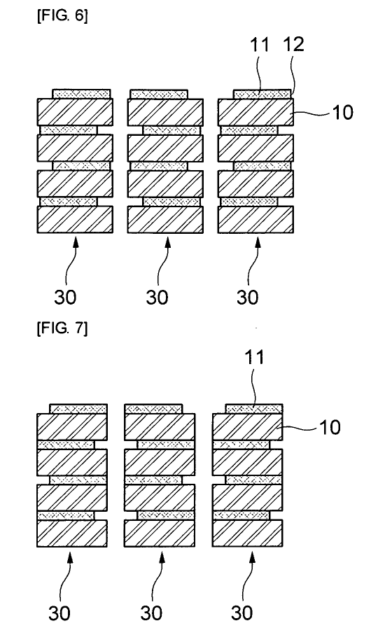

Hereinafter, a method of manufacturing the green chip using the above-mentioned green sheet for the multi-layered electronics parts will be described in detail with reference to FIGS. 3 to 7.

### Method of Manufacturing Green Chip Using Green Sheet for Multi-Layered Electronics Parts

FIGS. 3 to 7 are process cross-sectional views sequentially shown to illustrate the method of manufacturing the green chip using the green sheet for the multi-layered electronics parts in accordance with the embodiment of the present invention.

First, as shown in FIG. 3, a plurality of green sheets 10 are provided.

After then, as shown in FIG. 4, the internal electrode 11 having the gap 12 formed therein is formed on each of the green sheets 10.

The gap 12 formed in the internal electrode 11 is an area cut in the cutting process for manufacturing green chips 30 to be described. The gap 12 is preferably formed in a center portion of the internal electrode 11.

As shown in FIG. 2, the internal electrode 11 having the gap 12 formed therein may be formed by using the mask 100 for exposing the internal electrode forming area 110 and covering the gap forming area 120.

The internal electrode 11 having the gap 12 formed therein may be formed by the above-mentioned screen printing method or vacuum thin-film depositing method.

Next, as shown in FIG. 5, each of the plurality of green sheets 10 on which the internal electrode 11 is formed is stacked.

Herein, the gap 12 may be positioned on a cutting line D between the adjacent internal electrodes 11 at the time of stacking each of the green sheets 10.

After then, each of the green chips 30 is manufactured as shown in FIG. 6 by cutting each of the stacked green sheets 10 along a center of the gap 12 of the internal electrode 11, which serves as the cutting line D.

In the cutting process for manufacturing each of the green chips 30, the green sheet 10 may be cut along the cutting line D by using a blade 200.

At this time, since the blade 200 is in contact with the internal electrode 11 and thus the green chips 30 are difficult to cut in the cutting process for manufacturing the green chips 30 in case that a width l₁ of the gap 12 is smaller than a width l₂ of the blade 200, the width l₁ of the gap 12 is preferably equal to or larger than the width l₂ of the blade 200.

At this time, by the method for manufacturing the green chips using the green sheet for the multi-layered electronics parts in accordance with the embodiment of the present invention, since the cutting stress and the cutting damage can be minimized by forming the internal electrode 11 having the gap 12 formed therein on the green sheet 10 and cutting not the internal electrode 11 but the gap 12 in the cutting process for manufacturing the green chips 30, the defect rate of the green chip can be reduced, thereby improving the yield and reliability of the green chip.

Then, as shown in FIG. 7, a polishing process for removing the gap 12 is performed. The internal electrode 11 may be exposed to the outside by removing the gap 12 remaining after the cutting process in the polishing process.

As described above, by the green sheet for the multi-layered electronics parts and the method of manufacturing the same in accordance with the present invention, the cutting stress and the cutting damage can be minimized by forming the gap in the internal electrode of the green sheet and cutting not the internal electrode but the gap in the cutting process for manufacturing the green chips, thereby reducing the failure rate of the chip.

Accordingly, the present invention has an advantage in that the yield and reliability of the green chip can be improved.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

1. A green sheet for multi-layered electronics parts comprising:
a green sheet; and
an internal electrode formed on the green sheet and being provided with a gap formed therein.

2. The green sheet for the multi-layered electronics parts according to claim 1, wherein the gap is formed in a center portion of the internal electrode.

3. The green sheet for the multi-layered electronics parts according to claim 1, wherein the internal electrode is formed by a screen printing method or a vacuum thin-film depositing method.

4. A method of manufacturing a green chip using a green sheet for multi-layered electronics parts comprising:
providing a green sheet;
forming an internal electrode with a gap formed therein on the green sheet;
stacking the green sheet in which the internal electrode is formed; and
cutting the stacked green sheet along a center of the gap of the internal electrode, which serves as a cutting line.

5. The method of manufacturing the green chip using the green sheet for the multi-layered electronics parts according to claim 4, wherein the gap is formed in a center portion of the internal electrode.

6. The method of manufacturing the green chip using the green sheet for the multi-layered electronics parts according to claim 4, wherein the internal electrode is formed by a screen printing method or a vacuum thin-film depositing method.

7. The method of manufacturing the green chip using the green sheet for the multi-layered electronics parts according to claim 4, wherein, in the stacking, the gap is positioned on the cutting line between adjacent internal electrodes at the time of stacking the green sheet.

8. The method of manufacturing the green chip using the multi-layered electronics parts according to claim 4, further includes a polishing to remove the gap after the cutting.

9. The method of manufacturing the green chip using the multi-layered electronics parts according to claim 4, wherein, in the cutting, the green sheet is cut by using a blade along the cutting line and a width of the gap is equal to or larger than a width of the blade.
